(19) United States
(12) Patent Application Publication
(10) Pub. No.: US 2025/0220955 A1
(43) Pub. Date: Jul. 3, 2025

(54) POWER MOSFET DEVICE HAVING IMPROVED SAFE-OPERATING AREA AND ON RESISTANCE, MANUFACTURING PROCESS THEREOF AND OPERATING METHOD THEREOF

(71) Applicant: STMicroelectronics S.r.l., Agrate Brianza (IT)

(72) Inventors: Angelo MAGRI', Belpasso (IT); Stefania FORTUNA, AciBonaccorsi (IT)

(73) Assignee: STMicroelectronics S.r.l., Agrate Brianza (IT)

(21) Appl. No.: 19/087,852

(22) Filed: Mar. 24, 2025

Related U.S. Application Data
(63) Continuation of application No. 18/335,916, filed on Jun. 15, 2023.
Application No. 18/335,916 is a division of application No. 17/096,697, filed on Nov. 12, 2020, now Pat. No. 11,728,422.

(30) Foreign Application Priority Data
Nov. 14, 2019 (IT) 102019000021171

(51) Int. Cl. H10D 30/66; H01L 21/265; H01L 21/765; H10D 30/01; H10D 62/10; H10D 62/17; H10D 64/00

(52) U.S. Cl. CPC H10D 30/668; H01L 21/26513; H01L 21/765; H10D 30/0297; H10D 62/127; H10D 62/393; H10D 64/117

(57) ABSTRACT

A power MOSFET device includes an active area accommodating a first body region and a second body region having a first and, respectively, a second conductivity value. The second value is higher than the first value. A first channel region is disposed in the first body region between a first source region and a drain region, and the first channel region has and having a first channel length. A second channel region is disposed in the second body region between a second source region and the drain region, and the second channel region has and having a second channel length smaller than the first channel length. A first device portion, having a first threshold voltage, includes the first channel region, and a second device portion, having a second threshold voltage higher than the first threshold voltage, includes the second channel region.

### BACKGROUND

### Technical Field

The present disclosure relates to a power MOSFET device having improved safe-operating area and ON resistance, to the manufacturing process thereof and to the operating method thereof.

### Description of the Related Art

As is known, power devices are electronic devices that are adapted to work at high voltages and/or currents, for example with voltages that reach 1700 V in inhibition state, and with currents of up to several tens/hundreds of amps, and find use in multiple fields of application. For instance, they are commonly used in audio amplifiers, engine-control devices, and power supplies or power switches, and include power diodes, power transistors, thyristors, IGBTs (Insulated-Gate Bipolar Transistors), and MOSFETs (Metal-Oxide-Semiconductor Field-Effect Transistors).

In particular, in the case of power MOSFET devices, they are at times used in saturation mode (operation in active region) as sources of constant current, which is regulated by varying the value of the gate-to-source voltage V_{GS}. In fact, in saturation mode, the drain-to-source current I_{DS} is practically independent of the drain-to-source voltage VDs, but varies as a function of the voltage V_{GS}.

In different applications, the power MOSFET device operates in linear mode (also referred to as ohmic or triode region), switching from an ON state to an OFF state, and vice versa. The linear mode is characterized by a linear relation between the current I_{DS} and the voltage VDS, and therefore by a constant value of drain-to-source ON resistance R_{DSon} (also referred to hereinafter as ON resistance R_{DSon}). In this operating mode, the switching rate between the OFF and ON states affects the characteristics of the power MOSFET device. In fact, the slower is the transition from the ON state to the OFF state, the greater is the power dissipation during the switching, and the greater is the likelihood of a thermal drift of the threshold voltage V_{TH} of the power MOSFET device, as explained hereinafter.

In particular, the thermal drift is caused by a phenomenon of positive reaction that involves the threshold voltage V_{TH} and the junction temperature T_{J} of the power MOSFET device (i.e., the maximum operating temperature of a semiconductor body in the power MOSFET device). In fact, an increase in the junction temperature T_{J} by the Joule effect causes a reduction of the threshold voltage V_{TH}, the flowing of a higher current, and a further increase in the junction temperature T_{J}.

In order to reduce power dissipation, power MOSFET devices are currently designed so as to present a low ON resistance R_{DSon}, enabling considerable gains in efficiency at high switching frequencies. The reduction of the ON resistance R_{DSon} makes, however, the power MOSFET device less stable from a thermal standpoint when it operates in saturation mode, on account of the higher current-carrying capacity given the same voltage V_{GS} applied.

As is known, each power MOSFET is characterized by an FBSOA (Forward-Biased Safe-Operating Area) delimited by a curve that defines the maximum values of the drain-to-source voltage V_{DS} and of the drain-to-source current I_{DS} in which it operates properly. Moreover, each power MOSFET has a current I_{DS} transfer characteristic as a function of the gate-to-source voltage V_{GS}, as the junction temperature T_{J} varies in a parametric way, illustrated in FIG. 1. In detail, FIG. 1 shows qualitatively the transfer characteristics at a first junction temperature T_{J,1}, a second junction temperature T_{J,2}, and a third junction temperature T_{J,3} (where T_{J,1}<T_{J,2}<T_{J,3}, and for example T_{J,1}=−55° C., T_{J,2}=25° C., and T_{J,3}=150° C.). As may be noted, each of the transfer characteristics has an increasing trend as the voltage V_{GS} increases. Moreover, the above transfer characteristics intersect each other at a ZTC point (Zero Temperature Coefficient) corresponding to a ZTC voltage V_{GS(ZTC)} and a ZTC current I_{DS(ZTC)}. Consequently, for V_{GS}=V_{GS(ZTC)}, the current IDs of the power MOSFET remains stable and unvaried as the junction temperature T_{J} varies. For V_{GS}>V_{GS(ZTC)}, the current I_{DS} decreases as the junction temperature T_{J} increases (in other words, the ratio between the variation of the saturation current density J_{DS,sat} and the variation of the junction temperature T_{J} has a negative value, i.e., ΔJ_{DS,sat}/ΔT_{J}<0), thus guaranteeing a condition of thermal stability of the power MOSFET (stability region). Instead, for V_{GS}<V_{GS(ZTC)}, the current I_{DS} increases as the junction temperature T_{J} increases (in other words, the ratio between the variation of the saturation current density J_{DS,sat} and the variation of the junction temperature T_{J} has a positive value, i.e., ΔJ_{DS,sat}/ΔT_{J}>0), causing a condition of thermal instability of the power MOSFET (instability region). In fact, for V_{GS}<V_{GS(ZTC)} the process of breakdown of the power MOSFET by thermal drift occurs.

Known solutions to the above problem envisage designing the power MOSFET so as to reduce the values of the ZTC voltage V_{GS(ZTC)} and of the ZTC current I_{DS(ZTC)}, thus minimizing the corresponding instability region. However, it has been demonstrated that there exists an inverse dependence between the ZTC point and the ON resistance R_{DSon}: the lower is the ZTC point (i.e., the lower are the ZTC voltage V_{GS(ZTC)} and the ZTC current I_{DS(ZTC)}), the higher is the ON resistance R_{DSon}. Consequently, modern MOSFET technologies, which guarantee excellent performance at high power and high switching frequency, are characterized by low ON resistances R_{DSon} (and therefore by good performance when they operate in the ohmic region) but tend to be intrinsically less robust to phenomena of thermal drift.

In the production of current power devices a compromise is therefore reached between the ON resistance R_{DSon} and the ZTC point (which is indicative of thermal stability), which leads to optimization of the use of such devices either in the saturation region or in the linear region.

### BRIEF SUMMARY

In various embodiments, the present disclosure provides a power MOSFET device that solves the problems of known devices and in particular enables better values of ON resistance and operating area to be achieved.

According to the present disclosure, a power MOSFET device, a manufacturing process thereof and an operating method thereof are provided.

### BRIEF DESCRIPTION OF THE SEVERAL VIEWS OF THE DRAWINGS

For a better understanding of the present disclosure, preferred embodiments thereof are now described purely by way of non-limiting example and with reference to the attached drawings, wherein:

FIG. 1 shows the characteristic of the current as a function of the gate voltage in a power MOSFET, as a junction temperature varies in a parametric way;

FIG. 2 is a cross-sectional view, taken along the lines of section II-II of FIG. 3, of a power device according to one embodiment;

FIG. 3 is a cross-sectional view, taken along the lines of section III-III of FIG. 2, of the power device of FIG. 2;

FIG. 4A shows the output characteristics of the power device of FIG. 2 in different operating modes thereof;

FIG. 4B shows the comparison between characteristics of thermal stability of the power device of FIG. 2 and of a power MOSFET of a known type;

FIGS. 5-7 are sections, analogous to that of FIG. 2, of different embodiments of the power device;

FIGS. 8A-8C show, in the same cross-sectional view as that of FIG. 2, successive steps of a manufacturing process of the power device of FIG. 2, according to one embodiment; and

FIGS. 9-10 are sections, analogous to that of FIG. 2, of further embodiments of the power device.

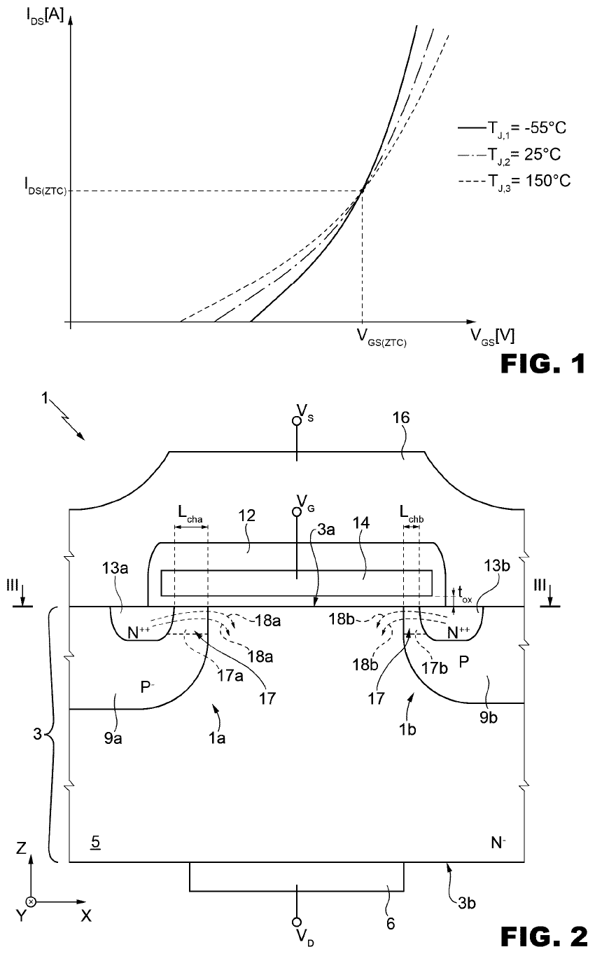

### DETAILED DESCRIPTION

In the ensuing description, elements that are in common in the various embodiments are indicated with the same reference numbers.

FIG. 2 shows a power device (or power MOSFET device) 1, which in the embodiment described by way of example includes a first device portion 1a and a second device portion 1b. The power device 1 has a main extension parallel to a first axis Y of a Cartesian reference system XYZ, and FIG. 2 shows a cross-sectional view perpendicular to said main extension.

The power device 1 includes a semiconductor body 3, for example of silicon, having a front surface 3a and a rear surface 3b. The semiconductor body 3 accommodates a drain region 5, which has a first conductivity type (for example, an N type conductivity) and a first conductivity value and extends in the semiconductor body 3 starting from the rear surface 3b towards the front surface 3a. A drain metallization 6 extends on the rear surface 3b, in direct electrical contact with the drain region 5 and forms a drain electrical terminal.

A first body region 9a and a second body region 9b extend in the semiconductor body 3 starting from the front surface 3a towards the rear surface 3b and are physically separated from one another (in a direction parallel to a second axis X of the Cartesian system XYZ) and from the rear surface 3b (in a direction parallel to a third Cartesian axis Z) by the drain region 5. Both the first body region 9a and the second body region 9b have a second conductivity type (here, a P type conductivity). In particular, the first body region 9a has a second conductivity value, whereas the second body region 9b has a third conductivity value, higher than the second conductivity value.

A first source region 13a and a second source region 13b, having the first conductivity type (here, an N type conductivity) and a fourth conductivity value, higher than the first, extend within the first and second body regions 9a, 9b, respectively, starting from the front surface 3a. In a direction parallel to the second axis X, each source region 13a, 13b is physically separated (i.e., set at a distance) from the drain region 5 by a respective portion of the first and second body regions 9a, 9b, respectively, which form a first channel region 17a and a second channel region 17b, respectively (which therefore have, respectively, the second and, respectively, the third conductivity value higher than the second conductivity value). In particular, the first channel region 17a has, in a direction parallel to the second axis X, a first channel length L_{cha} measured at the front surface 3a, whereas the second channel region 17b has, in a direction parallel to the second axis X, a second channel length L_{chb} measured at the front surface 3a. The channel lengths L_{cha}, L_{chb} are different from one another. In detail, in the embodiment of FIG. 2, the first channel length L_{cha} is greater than the second channel length L_{chb}.

In particular, in a manner known to the person skilled in the art, the conductivity values of the body regions 9a and 9b are chosen, together with other design parameters, so as to set the threshold voltages Vth at desired values and in particular, as discussed in detail hereinafter, so as to cause the first device portion 1a to turn on at a lower value of the gate voltage VG than the second device portion 1b.

In one embodiment, the power device 1 can have a first channel length L_{cha} comprised between 150 nm and 1000 nm, in particular approximately 500 nm, and a second channel length L_{chb} comprised between 100 nm and 900 nm, in particular approximately 350 nm. Moreover, during fabrication and as described in detail hereinafter, the first doping value for obtaining the drain region 5 is comprised between 1·10¹⁴ ions/cm³ and 5·10¹⁶ ions/cm³, for example approximately 2·10¹⁶ ions/cm³, the second doping value for implantation of the first body region 9a is comprised approximately between 1·10¹² ions/cm² and 1·10¹³ ions/cm², the third doping value for implantation of the second body region 9b is comprised approximately between 5·10¹² ions/cm² and 5·10¹³ ions/cm², and the fourth doping value for implantation of the source regions 13a, 13b is comprised between 5·10¹⁵ ions/cm² and 5·10¹⁶ ions/cm², for example approximately 1·10¹⁶ ions/cm².

The power device 1 moreover has an oxide layer 12 on the front surface 3a. The oxide layer 12 is, for example, of silicon dioxide (SiO₂) and surrounds a gate region 14 of conductive material (for example, metal or doped polysilicon) so as to insulate the gate region 14 physically and electrically from the front surface 3a of the semiconductor body 3. The gate region 14 is moreover electrically connected to a gate metallization (not illustrated) in a per se known manner to the person skilled in the art.

A source metallization 16 (defining a source electrical terminal of conductive material, such as metal) extends on the oxide layer 12 and on the front surface 3a, where the latter is not covered by the oxide layer 12, and is in direct electrical contact with the source regions 13a, 13b and the body regions 9a, 9b, which are therefore electrically coupled together.

In practice, the drain metallization 6, the drain region 5, the first body region 9a, the first source region 13a, the gate region 14, the oxide layer 12, and the source metallization 16 form the first device portion 1a, whereas the drain metallization 6, the drain region 5, the second body region 9b, the second source region 13b, the gate region 14, the oxide layer 12, and the source metallization 16 form the second device portion 1b.

The first device portion 1a is therefore characterized by the first channel length L_{cha} and by the second conductivity value of the first body region 9a, whereas the second device portion 1b is characterized by the second channel length L_{chb} and by the third conductivity value of the second body region 9b.

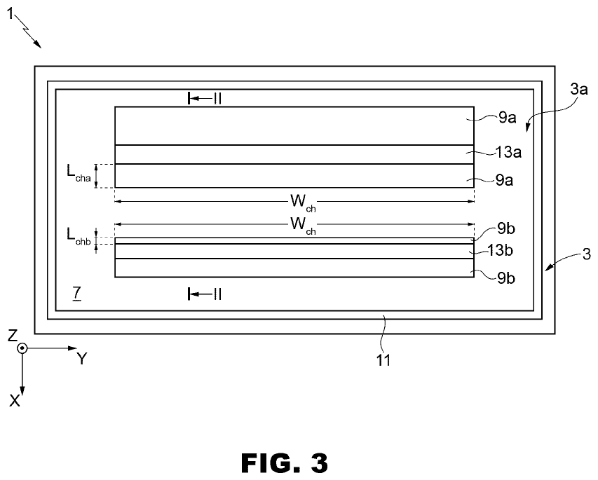

As may be noted from FIG. 3, the channel regions 17a, 17b of the device portions 1a, 1b have widths, in a direction parallel to the first axis Y, that are the same as one another and equal to a channel extension W_{ch} (also referred to as channel width W_{ch}).

Moreover, as may be seen from FIG. 3, both of the device portions 1a, 1b extend within an active region 7 of the power device 1. In particular, the semiconductor body 3 includes a field insulation region 11 (of insulating material, such as SiO₂), having a closed shape and delimiting the active region 7 of the power device 1. The insulation region 11 has the function of electrically insulating the active region 7 (and therefore the power device 1a, 1b) from the remaining portion of semiconductor body 3. The active region 7, and the device portions 1a and 1b included therein, are therefore galvanically insulated from possible devices comprised in the semiconductor body 3 but external to the active region 7.

In a known manner, during use, the power device 1 is biased by applying a source voltage V_{S} to the source metallization 16 (for example, a ground reference voltage GND), whereas a drain voltage VD (e.g., from 30 V to 1700 V) is applied to the drain metallization 6. Moreover, when the power device is in the conduction state, the gate region 14 is biased at a gate voltage VG such as to generate respective flows of charge carriers (here electrons) 18a, 18b through, respectively, the channel regions 17a, 17b, (as illustrated in FIG. 2).

In use, the total conduction of the power device 1 is therefore a function of both of the electron flows 18a, 18b (each corresponding to a respective device portion 1a, 1b).

As is known, in power MOSFETs the following relations apply:

$${I}_{DSsat} ∼ \frac{{W}_{ch} \cdot μ}{{t}_{ox} \cdot {L}_{ch}} {( {V}_{G} - {V}_{TH} )}^{2} \\ {R}_{DSon} ∼ {R}_{0} + \frac{{t}_{ox} \cdot {L}_{ch}}{{W}_{ch} \cdot μ} \cdot \frac{1}{{V}_{G} - {V}_{TH}} \\ {V}_{TH} ∼ {t}_{ox} \cdot \sqrt{{N}_{A}}$$

where I_{DSsat} is the drain-source current (also referred to hereinafter as first current Ia when referring to the first device portion 1a and second current Ib when referring to the second device portion 1b), W_{ch} is the channel extension, V_{TH} is the threshold voltage (i.e., the minimum potential difference that can be applied between the gate region 14 and the source regions 13a, 13b of the device portions 1a, 1b to form the respective conduction channels), R_{DSon} is the ON resistance, tₒₓ is the thickness of the oxide layer 12 (measured parallel to the third axis Z, and for example comprised between 20 nm and 150 nm), NA is the concentration of channel dopant ions (linked to the second conductivity value for the first body region 9a, and to the third conductivity value for the second body region 9b), μ is the mobility of the charge carriers (here electrons), and R₀ is an offset value of the ON resistance that depends both upon the maximum voltage V_{DS} sustainable by the power device 1 in the inhibition state and by the parasitic resistive contributions associated to the connection of the drain and source terminals.

In particular, since the conductivity values of the body regions 9a, 9b are different from one another, the device portions 1a, 1b have threshold voltages V_{TH} different from one another (a first threshold voltage V_{THa} for the first device portion 1a and a second threshold voltage V_{THb} for the second device portion 1b). In particular, in the considered embodiment, the first threshold voltage V_{THa} is lower than the second threshold voltage V_{THb} (for example, the first threshold voltage V_{THa} is equal to 3 V, and the second threshold voltage V_{THb} is equal to 6 V). Moreover, since the channel lengths L_{cha}, L_{chb} are different from one another, the device portions 1a, 1b have ON resistances R_{DSon} different from one another (a first ON resistance R_{DSona} for the first device portion 1a, and a second ON resistance R_{DSonb} for the second device portion 1b). In detail, the first ON resistance R_{DSona} is greater than the second ON resistance R_{DSonb} in a proportion that depends upon the ratio between the two different channel lengths L_{cha}, L_{chb}. By varying the conductivity values of the body regions 9a, 9b and the channel lengths L_{cha}, L_{chb} it is therefore possible to obtain different behaviors from the device portions 1a, 1b, also taking into account the fact that the saturation current I_{DSsat} depends in a quadratic way (therefore with a second-degree dependence) upon the threshold voltage V_{TH}, whereas the ON resistance R_{DSon} depends in an inversely proportional way (therefore with a first-degree dependence) upon the threshold voltage V_{TH} (linked to the conductivity values of the body regions 9a, 9b).

In use, the power device 1 switches from the OFF state to the ON state, and vice versa.

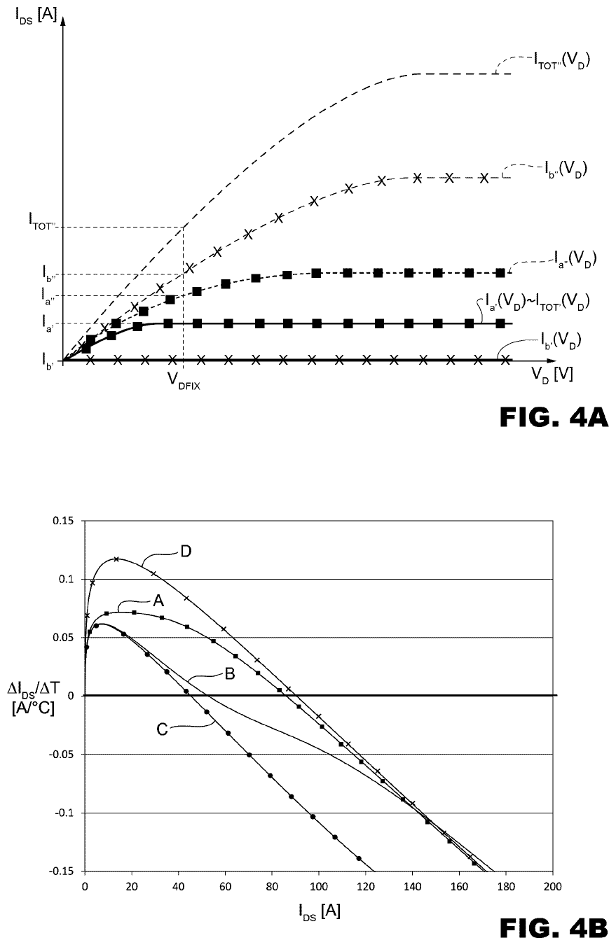

With reference to the transition from the OFF state to the ON state, as illustrated in FIG. 4A, the power device 1 starts switching as the gate voltage V_{G} increases with respect to an OFF value (for example, equal to 0 V), with the drain voltage V_{D} set at a value V_{DFIX}. When the gate voltage V_{G} reaches the first threshold voltage V_{THa} and is lower than the second threshold voltage V_{THb} (first operating mode, where the gate voltage V_{G} has a first value V_{G1}), the first device portion 1a starts to switch on (first value I_{a′} of the first current Iₐ), while the second device portion 1b is still turned off (in the inhibition state; i.e., it has a first value I_{b′} of the second current I_{b} that is substantially zero) given that it has a higher value of the threshold voltage V_{TH}. Considering that the overall performance of the power device 1 is given by a total current I_{TOT}, sum of the first current Iₐ and the second current I_{b}, the power device 1 works here only with the first device portion 1a. In other words, a first value I_{TOT′} of the total current I_{TOT} is substantially equal to the first value I_{a′} of the first current Iₐ, given that the first value I_{b′} of the second current I_{b} is substantially zero. In the typical conditions (and in particular at the of gate voltage V_{G} and drain voltage V_{D} used) in which the power device 1 operates, its overall behavior substantially coincides with the saturation mode of the first device portion 1a, with a low value of total current I_{TOT} and a good thermal stability.

When the gate voltage V_{G} exceeds the second threshold voltage V_{THb} (second operating mode, where the gate voltage V_{G} has a second value V_{G2}), both the first device portion 1a and the second device portion 1b are active (i.e., they have a second value I_{a″} of the first current Iₐ and, respectively, a second value I_{b″} of the second current I_{b}, that are both non-zero); therefore, the total current I_{TOT} has a second value I_{TOT″} equal to the sum of the second value I_{a″} of the first current Iₐ and of the second value I_{b″} of the second current I_{b}. In particular, here, in the typical conditions (and in particular at the gate voltages V_{G} and drain voltages V_{D} used) in which the power device 1 operates, both the first device portion 1a and the second device portion 1b operate in the ohmic region. At high gate voltages V_{G}, the overall behavior of the power device 1 is therefore substantially the ohmic mode for both of the device portions 1a and 1b, with a low value of ON resistance R_{DSon}. Moreover, the second value I_{TOT″} of the total current I_{TOT} is higher than the first value I_{TOT}′ of the total current I_{TOT}. Furthermore, the aforesaid high values of gate voltage V_{G} are higher than the ZTC point of the power device 1, which therefore does not present thermal drift issues.

FIG. 4B shows the comparison between instability areas of the power device 1 (defined by curves A, B, C, calculated as the difference between the threshold voltages V_{THa}, V_{THb} varies in a parametric way) and an instability area of a power MOSFET of a known type (defined by a curve D), optimized for working in the ohmic region. The curve A is calculated by setting the difference between the threshold voltages V_{THa}, V_{THb} at 1 V, the curve B is calculated by setting the difference between the threshold voltages V_{THa}, V_{THb} at 2 V, and curve C is calculated by setting the difference between the threshold voltages V_{THa}, V_{THb} at 3 V. Each instability area is the area subtended by positive values of the respective curve defined by a coefficient ΔI_{DS}/ΔT, as a function of the current I_{DS} (saturation current I_{DSsat}). In particular, the instability area of the power device 1 is lower than that of the power MOSFET of a known type, and decreases as the difference between the first and second threshold voltages V_{THa}, V_{THb} increases.

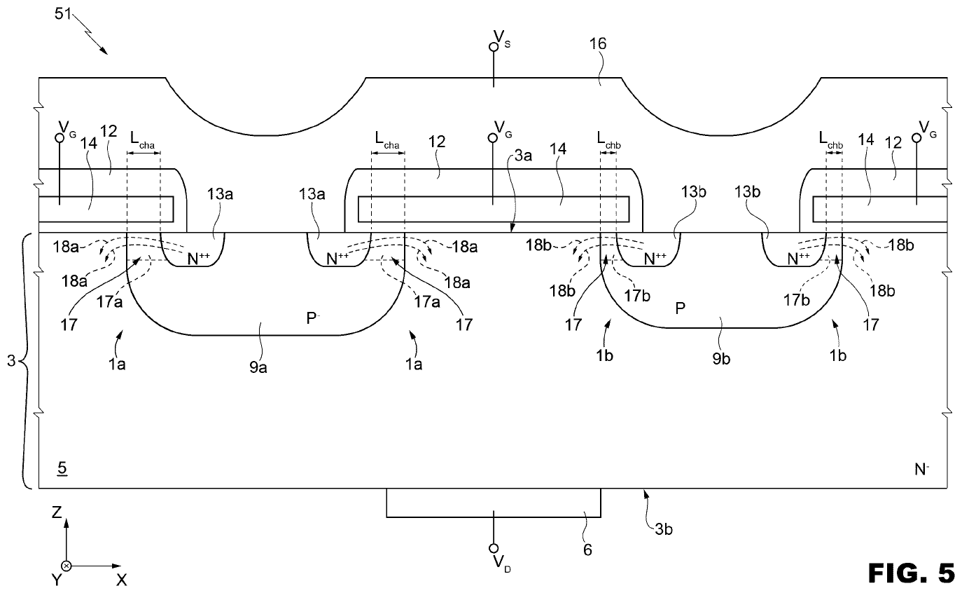

FIG. 5 shows a different embodiment of the power device (indicated in FIG. 5 with the reference number 51). The power device 51 includes a plurality of first and second device regions 1a, 1b (each of which is analogous to the first device region 1a and, respectively, to the second device region 1b of FIG. 2), included in an active region (analogous to the active region 7 of FIG. 3). In particular, FIG. 5 shows two first device regions 1a and two second device regions 1b, even though the number may vary according to the needs or design considerations.

In the embodiment provided by way of example in FIG. 5, each first body region 9a accommodates two first source regions 13a, physically distanced between each other by a portion of the first body region 9a itself. Said first source regions 13a extend in the first body region 9a substantially to a same depth (measured along the first axis Y), and each first source region 13a is physically distanced from the drain region 5, along the second axis X, by a distance equal to the first channel length L_{cha} (thus forming respective first channel regions 17a). Likewise, each second body region 9b accommodates two second source regions 13b, physically distanced between each other by a portion of the second body region 9b itself. Said second source regions 13b extend in the second body region 9b substantially to a same depth (measured along the first axis Y), and each second source region 13b is physically distanced from the drain region 5, along the second axis X, by a distance equal to the second channel length L_{chb} (thus forming respective second channel regions 17b).

In the section of FIG. 5, the first body regions 9a and the second body regions 9b are arranged so as to alternate with one another, to form an array along the second axis X. Consequently, each first channel region 17a faces, via the drain region 5, a respective second channel region 17b (and vice versa).

The power device 51 further includes a plurality of gate regions 14. In particular, each gate region 14 extends on the two channel regions 17a, 17b that face one another, as well as on the portion of the drain region interposed between them, to form a structure analogous to the one illustrated in FIG. 2.

In use, all the gate regions 14 are set at the same gate voltage V_{G}, the source regions 13a, 13b are set at the same source voltage V_{S} (common also to the body regions 9a, 9b), and the drain region 5 is set, at the rear surface 3b, at the drain voltage V_{D}.

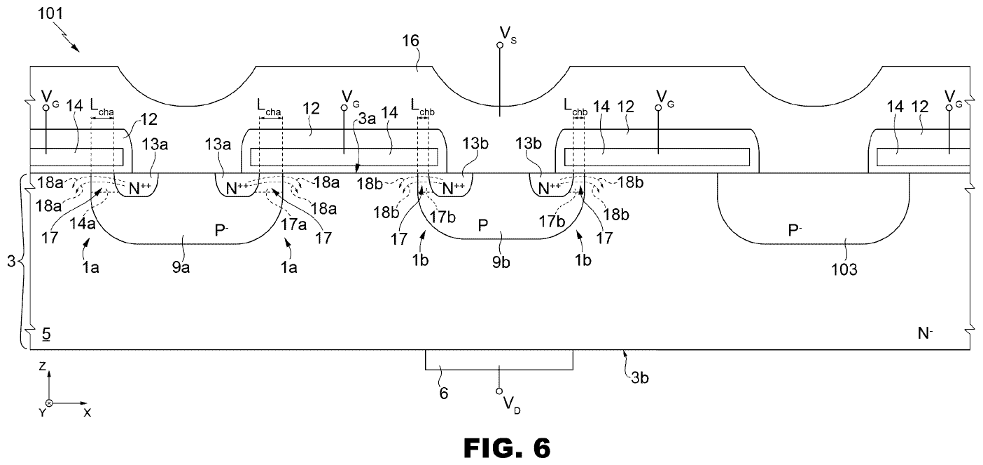

According to a different embodiment illustrated in FIG. 6, the power device, here indicated with the reference number 101, is analogous to the one represented in FIG. 5, but includes at least one doped region 103 having a conductivity type different from that of the semiconductor body 3 (and therefore here having a P type conductivity) and a value equal to the second conductivity value or, alternatively, to the third conductivity value. In particular, the at least one doped region 103 is present in the power device 101 in the place of at least one respective body region 9a, 9b, and is also included in the active region 7. For instance, FIG. 6 shows the presence of a doped region 103 in the power device 101, which replaces a respective first body region 9a (in this case, it has the second conductivity value). Considering, instead, the case wherein the power device includes a number of doped regions 103, the doped regions 103 can replace a respective number of body regions 9a, 9b in a random way or respecting a predefined relation (for example, in a periodic way in a direction parallel to the axis X).

The doped regions 103 differ structurally from the body regions 9a, 9b only as regards the absence of respective source regions 13a, 13b accommodated therein. The absence of source regions 13a, 13b leads to the impossibility, in said doped regions 103, of forming the device portions 1a, 1b (i.e., the impossibility of generating the conduction channels). Consequently, as the number of doped regions 103 increases, the number of device portions 1a, 1b present in the power device 101 decreases. The ON resistance R_{DSon} of the power device 101 therefore increases, and the latter presents greater thermal stability (since the overall maximum current-carrying capacity of the power device 101 decreases), given a less efficient use of the area of the power device 101.

In practice, this is due to the fact that the power device 101 presents an effective channel extension (width) W_{eff} smaller than a total channel extension (width) Wₜₒₜ. The effective channel extension W_{eff} is the sum of the channel extensions W_{ch} of the device portions 1a, 1b comprised in the power device. According to one embodiment, the effective channel extension W_{eff} is calculated according to the following expression:

$${W}_{eff} = 2 {W}_{ch} \cdot {n}_{body}$$

where n_{body} is the number of body regions 9a, 9b present in the power device 101.

The total channel extension Wₜₒₜ is, instead, calculated according to the following expression:

$${W}_{tot} = 2 {W}_{ch} \cdot ( {n}_{body} + {n}_{red} )$$

where n_{red} is a reduction value, here equal to the number of doped regions 103 present in the power device 101.

Considering the case provided by way of example, wherein, in a direction parallel to the second axis X, a doped region 103 is present every two body regions 9a, 9b, the total channel extension Wₜₒₜ and the effective channel extension W_{eff} are related to one another by the expression:

$${W}_{eff} = \frac{2}{3} {W}_{tot}$$

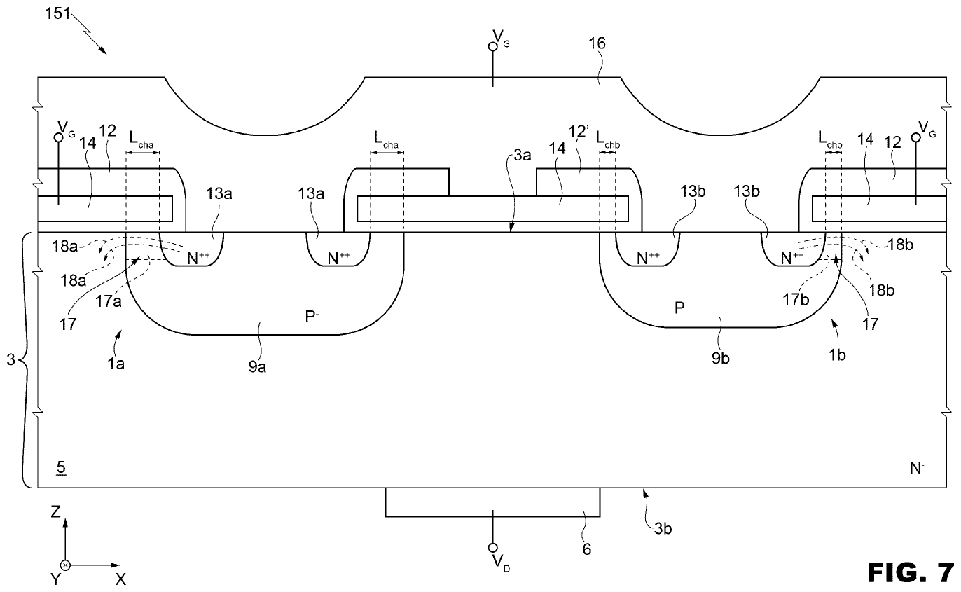

FIG. 7 shows a different embodiment of the power device, here indicated with the reference number 151, wherein the effective channel extension W_{eff} is smaller than the total channel extension Wₜₒₜ.

The power device 151 is analogous to the one represented in FIG. 5, except for the fact that at least one of the oxide layers 12 is, at least partially, recessed or in any case interrupted so as to form a respective interrupted-gate region 12′, where the gate region 14 and the source metallization 16 are in electrical and physical contact with one another. FIG. 7 shows by way of example the case where an interrupted-gate region 12′ is present. The interruption of the interrupted-gate region 12′ leads to equality between the gate voltage V_{G} of the respective gate region 14 and the source voltages V_{S} of the source regions 13a, 13b coupled thereto (therefore, the respective gate region 14 is in electrical contact with the respective source regions 13a, 13b). Consequently, the corresponding device portions 1a, 1b cannot enter into conduction and are thus inactive.

In the case where the power device includes a number of interrupted-gate regions 12′, these can be arranged in a random way or respecting a predefined relation (for example, in a periodic way in the direction of the second axis X). In particular, considering the case provided by way of example wherein, in a direction parallel to the second axis X, each oxide layer 12 alternates with an interrupted-gate region 12′, the reduction value n_{red} is equal to the number of interrupted-gate regions 12′, and the total channel extension Wₜₒₜ and the effective channel extension W_{eff} are related to one another by the expression:

$${W}_{eff} = \frac{1}{2} {W}_{tot}$$

Consequently, in use, the gate regions 14 included in the interrupted-gate regions 12′ are set at the same voltage as the source regions 13a, 13b (therefore, V_{G}=V_{S}, common also with the body regions 9a, 9b).

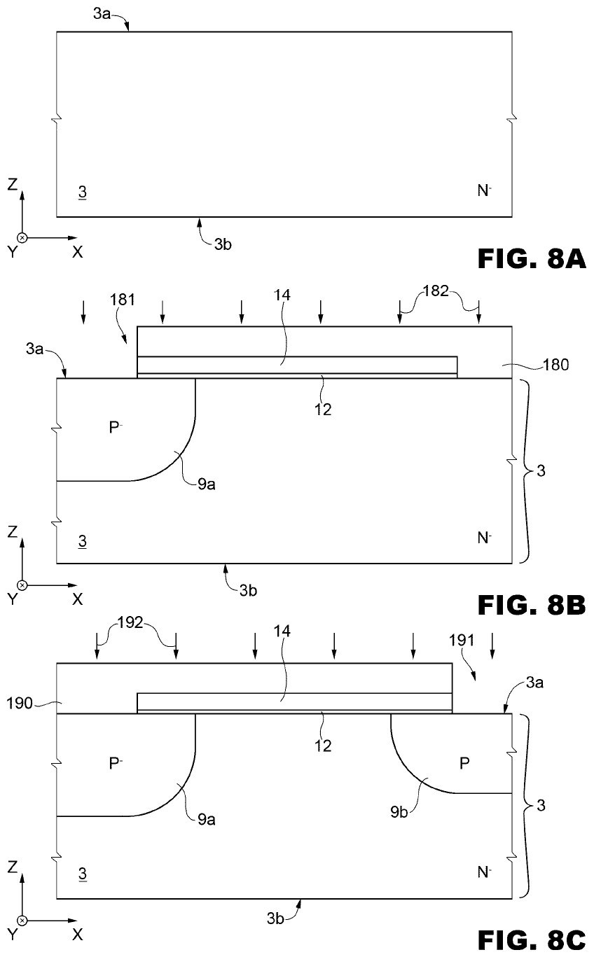

FIGS. 8A-8C show, instead, steps of a process for manufacturing the present power device. Even though the manufacturing process represented in FIGS. 8A-8C is provided by way of example, with reference to the power device 1 of FIG. 2, the fabrication of the power devices 51, 101, 151 is analogous and obvious to the person skilled in the art and therefore will not be described any further.

With reference to FIG. 8A, the manufacturing process comprises growing a plurality of epitaxial layers (not illustrated) on a substrate of semiconductor material, which has, in the context of the present description, an N conductivity. Each step of growth enables growing a respective epitaxial layer of a thickness, along the third axis Z, of some micrometers (e.g., 3-70 μm). The result of the epitaxial growth on the substrate is the formation of the drain region 5.

Then, via techniques in themselves known and starting from the front surface 3a, the insulation region 11 delimiting the active region 7 of the power device 1 is formed in the semiconductor body 3.

There then follow steps, which are in themselves known and will not be discussed any further, which lead to formation of at least part of the oxide layer 12 (in particular, of the portion of oxide layer 12 that is to be comprised between the gate region 14 and the front surface 3a) and, subsequently, to formation of the gate region 14.

With reference to FIG. 8B, there is deposited, on the front surface 3a of the semiconductor body 3 and on the gate region 14, a first photoresist layer 180 having a thickness, for example, comprised between 1 and 3 μm. Said first photoresist layer 180 coats the semiconductor body 3 entirely and in a uniform manner.

There then follows a step of photolithographic exposure of the first photoresist layer 180, via the use of a mask (not illustrated). The mask is such that a portion of the first photoresist layer 180 (at a first portion 181 of the front surface 3a of the semiconductor body 3) is exposed to lithographic exposure. The first portion 181 is arranged at the region of the semiconductor body 3 that is intended to accommodate the first body region 9a. The portions of the first photoresist layer 180 not covered by the mask thus become soluble during a subsequent etching step. Therefore, the etching step (e.g., of a wet type) is carried out to remove in a selective way the first photoresist layer 180 at the first portion 181, thus creating a first opening in the first photoresist layer 180. The photolithographic steps listed above have been described with reference to a positive photoresist. A different embodiment (not illustrated) envisages the use of a negative photoresist or of a bilayer, with appropriate modifications to the photolithographic mask used, in a manner in itself evident to the person skilled in the art. A first implantation (represented by arrows 182) of first dopants is then carried out through the first portion 181. In particular, the first dopants have a P type conductivity (for example, they are boron, indium, and aluminum ions) and a concentration equal to the second doping value mentioned above (approximately 1·10¹² to 1·10¹³ ions/cm²).

There then follow complete removal of the first photoresist layer 180 via etching or a lift-off process of a type in itself known, and a step of first thermal annealing that enables redistribution and activation of the first dopants; the first body region 9a is thus formed. This procedure is conducted in a protected environment (for example, in a nitrogen or argon atmosphere), at a temperature of between 900° C. and 1100° C. for a time comprised between a few tens of seconds (in the case of rapid thermal annealing, RTA) and a few hours (in the case of furnace annealing).

With reference to FIG. 8C, a second photoresist layer 190 is formed in a manner analogous to what is described with reference to FIG. 8B. In particular, the second photoresist layer 190 has a second opening that exposes a second portion 191 of the front surface 3a of the semiconductor body 3. In particular, the second opening is staggered, in top view (i.e., in a view parallel to the plane XY), with respect to the first opening. The second portion 191 is arranged at the region of the semiconductor body 3 that is intended to accommodate the second body region 9b. A second implantation (represented by arrows 192) of second dopants is then carried out in the second region 191. In particular, the second dopants have a P type conductivity and a concentration corresponding to the third doping value mentioned above (approximately 5·10¹² to 5·10¹³ ions/cm²).

There then follow complete removal of the second photoresist layer 190 via etching or a lift-off process of a type in itself known, and a step of first thermal annealing that enables redistribution and activation of the first dopants: the second body region 9b is thus formed. This procedure is conducted in a protected environment (for example, in a nitrogen or argon atmosphere), at a temperature of between 900° C. and 1100° C. for a time comprised between a few tens of seconds (in the case of rapid thermal annealing, RTA) and a few hours (in the case of furnace annealing).

There then follow steps that lead to formation of the power device 1 of FIG. 2, which are in themselves known and will not be discussed any further and which include formation of the source regions 13a, 13b via a further implantation of dopants (for example, arsenic, phosphorus, or antimony ions), and formation of the source metallization 16 and of the drain metallization 6. Nevertheless, it is considered obvious for the person skilled in the art that the formation of the source regions 13a, 13b may also be carried out, in a per se known manner, previously or simultaneously with formation of the body regions 9a, 9b.

With reference to FIG. 6, the doped region 103 is obtained using a mask that, during formation of the source regions 13a, 13b, covers the front surface 3a in the doped region 103.

With reference to FIG. 7, the interruption of the interrupted-gate region 12′ is obtained via selective etching of the oxide layer 12, which can be obtained with a mask that exposes the region of the oxide layer 12 to be removed.

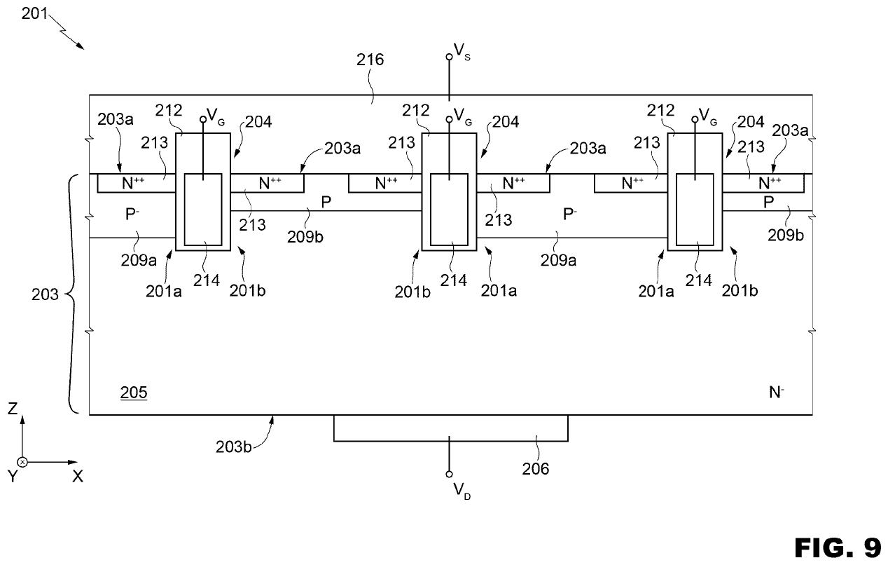

FIG. 9 shows a power device 201 having trench-gate regions included in a same active region (here not illustrated) of the power device 201. In particular, the power device 201 includes at least one first device portion with trench gate (also referred to hereinafter as first trench-gate portion 201a) and at least one second device portion with trench gate (also referred to hereinafter as second trench-gate portion 201b).

The power device 201 comprises a semiconductor body 203, for example of silicon, having a front surface 203a and a rear surface 203b. The semiconductor body 203 accommodates a drain region 205, which has the first conductivity type (for example, an N type conductivity) and the first conductivity value and extends in the semiconductor body 203 starting from the rear surface 203b towards the front surface 203a. A drain metallization 206 extends on the rear surface 203b, in direct electrical contact with the drain region 205, and forms a drain electrical terminal.

Insulated-gate regions 204 extend in the semiconductor body 203 starting from the front surface 203a towards the rear surface 203b. Illustrated by way of example in FIG. 9 are three insulated-gate regions 204; however, it is evident that they may be in any number. Each insulated-gate region 204 comprises an oxide layer 212, for example of silicon dioxide, which surrounds completely a gate region 214 of conductive material (for example, metal or doped polysilicon) so as to physically and electrically insulate the gate region 214 from the remaining part of the semiconductor body 203 and from a source metallization 216. In the case represented in the sectional view of FIG. 9, each insulated-gate region 204 has a substantially rectangular shape, the major sides of which extend approximately parallel to the third axis Z, perpendicular to the front surface 203a. Moreover, the insulated-gate regions 204 may project from the front surface 203a of the semiconductor body 203.

Source regions 213, having the first conductivity type (here, an N type conductivity) and the fourth conductivity value, extend in the semiconductor body 203 starting from the front surface 203a between adjacent pairs of insulated-gate regions 204. The source metallization 216 extends over the front surface 203a and the insulated-gate regions 204 and electrically couples the source regions 213 together.

Body regions 209a, 209b, having the second conductivity type (here a P type conductivity), extend in the semiconductor body 203 underneath the source regions 213, towards the rear surface 203b. In addition, a portion of each body region 209a, 209b extends through the respective source region 213 until it physically and electrically contacts the source metallization 216, at the front surface 203a of the semiconductor body 203. The first body regions 209a have the second conductivity value and an extension, along the third axis Z, equal to the first channel length L_{cha}. The second body regions 209b have the third conductivity value and an extension, along the third axis Z, equal to the second channel length L_{chb}. In FIG. 9, the first body regions 209a alternate, along the second axis X, with the second body regions 209b.

In this manner, two stacks extend alongside each insulated-gate region 204, wherein a first stack includes a source region 213, a first body region 209a, and part of the drain region 205, and a second stack includes a source region 213, a second body region 209b, and part of the drain region 205.

Each stack having the first body region 209a forms, with the two adjacent insulated-gate regions 204 and with the drain metallization 206 and the source metallization 216, two first device portions 201a, whereas each stack having the second body region 209b forms, with the two adjacent insulated-gate regions 204 and with the drain and source metallizations 206, 216, two second device portions 201b.

The semiconductor body 203 further includes an insulation region (not illustrated) delimiting the active area of the power device 201, as illustrated in FIG. 3.

In use, the portions of the body regions 209a, 209b contiguous to the insulated-gate regions 204 form conduction channels in a per se known manner.

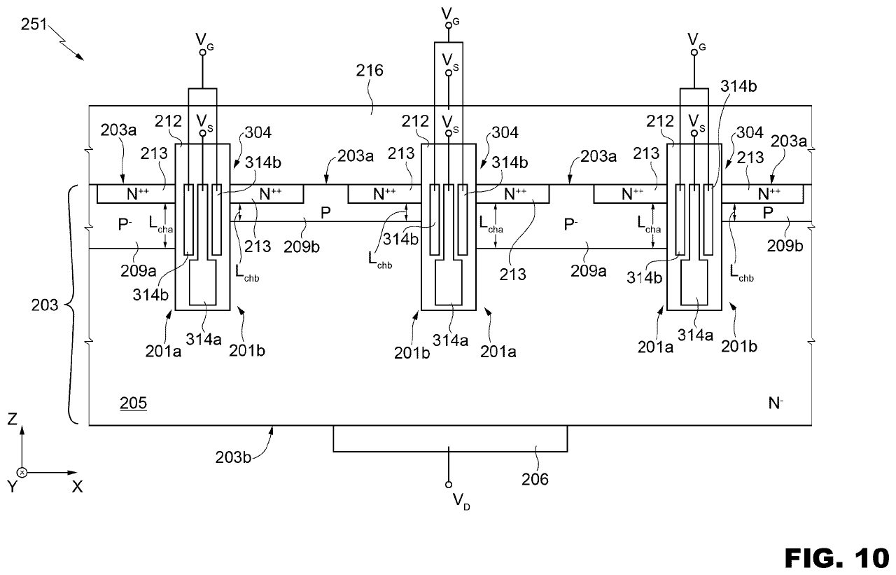

FIG. 10 shows a different embodiment of the power device (here indicated with the reference number 251), which is analogous to the power device 201 and differs from the latter in that of being of a known trench-split-gate type.

In detail, here, each insulated-gate region, indicated with 304, comprises an electrical-shielding region 314a, hereinafter referred to as field-plate region 314a, for example, of conductive material such as metal or doped polysilicon, and two split-gate regions 314b, for example, of metal or doped polysilicon. The field-plate region 314a has a shape elongated in the direction of the third axis Z, facing underneath the drain region 205. In the embodiment provided by way of example, in its top portion, approximately at the level of the source regions 213 and of the body regions 209a, 209b, the field-plate region 314a is interposed between the two split-gate regions 314b, which are electrically insulated both from the field-plate region 314a and from the adjacent stacks via the oxide layer 212.

In use, each field-plate region 314a is biased at the source voltage V_{S}, and each split-gate region 314b is biased at the gate voltage V_{G}.

According to an embodiment (not illustrated), in the power device 251 at least one insulated-gate region 304 has the split-gate regions 314b electrically disconnected from the split-gate regions 314b of the other insulated-gate regions 304 in order to reduce the effective channel extension W_{eff} with respect to the total channel extension Wₜₒₜ. In this embodiment, the reduction value n_{red} is equal to the number of pairs of split-gate regions 214b electrically disconnected from the split-gate regions 314b of the other insulated-gate regions 304.

The manufacturing processes of the power devices illustrated in FIGS. 9 and 10 are analogous to what has been described with reference to FIGS. 8A-8C.

Furthermore, the modifications discussed with reference to the embodiments in FIGS. 6 and 7 apply (even in combination with one another), in a manner that is obvious to the person skilled in the art, also to the embodiments of the power devices of FIGS. 9 and 10.

According to one embodiment, the first and second device portions, in all the solutions illustrated, are arranged as elements alternating with one another of a two-dimensional matrix. In particular, the device portions can alternate with one another in both directions of the matrix (for example, both horizontally and vertically) so as to present a checkerboard arrangement, wherein each first device portion (for example, having a position (i, j) in said matrix) has as first neighbors in the directions of the matrix (i.e., the cells of the matrix having the positions (i−1, j), (i, j−1), (i+1, j), and (i, j+1)) second device portions, and vice versa.

According to a further embodiment (not illustrated) of the present disclosure, the number N₁ of the first device portions is different from the number N₂ of the second device portions. Alternatively, or in addition, the channel extensions L_{ch} of the conduction channels of the device portions may be different from one another, and therefore it is possible to have a first effective channel extension W_{eff,a} (referring to the first device portion) and a second effective channel extension W_{eff,b} (referring to the second device portion) that are different from one another. In particular, according to one embodiment, the smaller between the first effective channel extension W_{eff,a} and the second effective channel extension W_{eff,b} is greater than a predefined value (for example, equal to 20% of the effective channel extension W_{eff}, and therefore it applies the relation min (W_{eff,a}, W_{eff,b})=0.2·W_{eff}).

From an examination of the characteristics of the power MOSFET device, of the manufacturing process thereof and of the operating method thereof obtained according to the present disclosure, the advantages that it affords are evident.

The present disclosure makes it possible to avoid and overcome the compromise between ON resistance R_{DSon} and thermal stability, which is common in currently known power devices. In fact, the coexistence in a same power device of at least two device portions, wherein a first portion is optimized for working in the saturation region, and a second portion is optimized for working in the ohmic region, allows to have a single power device with improved operation in both the operating regions, given that, here, the saturation current I_{DSsat} and the ON resistance R_{DSon} are decoupled from one another.

In particular, in the embodiments discussed previously, the first device portion 1a, 201a has a saturation current I_{DSsat} lower than that of the second device portion 1b, 201b, and makes it possible to operate the power device at low gate voltages V_{G} (for example, at gate voltages V_{G} lower than a threshold gate voltage V_{Gth}) with a better thermal stability (i.e., minimizing the instability region and the ZTC point). At high gate voltages V_{G} (for example, at gate voltages V_{G} higher than the threshold gate voltage V_{Gth}, and in particular at values of gate voltage V_{G} higher than the ZTC voltage V_{GS(ZTC)}), the second device portion 1b guarantees optimal operation of the power device in the linear region thanks to the low ON resistance R_{DSon}.

It is therefore possible to improve the stability (or ruggedness) of the power device, maintaining a good ON resistance R_{DSon}.

The present disclosure therefore guarantees, thanks to the low ON resistance R_{DSon}, a reduction in power consumption of the power device and in the area of substrate required. Moreover, by reducing the effective channel extension W_{eff} with respect to the total channel extension Wₜₒₜ, the stability of the power device further improves since the saturation current I_{DSsat} decreases given the same occupation of area.

Finally, it is clear that modifications and variations may be made to the power MOSFET device, to the manufacturing process thereof and to the operating method thereof described and illustrated herein, without thereby departing from the scope of the present disclosure.

In particular, what has been described previously applies, in a manner obvious to the person skilled in the art, to power devices based upon technology different from silicon technology, such as silicon-carbide (SiC) power devices.

In addition, what has been previously described applies, in a manner obvious to the person skilled in the art, also to P-channel device portions 1a, 1b, 201a, 201b.

Furthermore, what has been previously described applies, in a per se obvious manner to the person skilled in the art, also to horizontal-channel signal MOSFET devices (i.e., ones in which the source region and the drain region face a same side of the semiconductor body).

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a first body region having a first conductivity type;
a second body region having the first conductivity type;
a first source region having a second conductivity type different from the first conductivity type;
a second source region having the second conductivity type;
a first channel region within the first body region, and
a second channel region within the second body region, the first channel region has a first channel length along a first direction, and the second channel region has a second channel length along the first direction, the second channel length is less than the first channel length; and
an insulated-gate region extending over the first channel region and the second channel region, the insulated-gate region including a gate region of a conductive material and an oxide layer covering the gate region, and the gate region extends over the first channel region and the second channel region.

2. The device of claim 1, wherein the first body region, the first source region, the drain region, the first portion of the insulated-gate region, and the first channel region form a first device portion having a first threshold voltage, and the second body region, the second source region, the drain region, the second portion of the insulated-gate region, and the second channel region form a second device portion having a second threshold voltage different from the first threshold voltage.

3. The device of claim 2, wherein the second threshold voltage is higher than the first threshold voltage.

4. The device of claim 1, wherein the gate region fully overlaps the first channel region and fully overlaps the second channel region.

5. The device of claim 1, wherein the second channel length is different from the first channel length.

6. The device of claim 1, wherein the oxide layer and the gate region fully overlap the first channel region and the second channel region.

7. The device of claim 1, wherein the gate region overlaps the first channel region and overlaps the second channel region.

8. The device of claim 1, wherein the gate region overlaps the first source region and overlaps the second source region.

9. The device of claim 1, wherein the gate region includes:
a first end that extends to the first source region and terminates over the first source region; and
a second end that extends to the second source region and terminates over the second source region.

10. A device, comprising:
a silicon carbide substrate of a first conductivity type;
a first body region in the silicon carbide substrate, the first body region having a second conductivity type;
a second body region in the silicon carbide substrate, the second body region having the second conductivity type, the second body region spaced from the first body region;
a portion of the silicon carbide substrate being between a first edge of the first body region and a second edge of the second body region;
a first source region spaced from a second source region, the first source region being in the first body region and the second source region being in the second body region, the first and second source regions having the first conductivity type, the first source region is spaced apart from the portion of the silicon carbide substrate by the first body region by a first dimension in a first direction, and the second source region is spaced apart from the portion of the silicon carbide substrate by the second body region by a second dimension in the first direction, and the first dimension is different from the second dimension;
a gate electrode that completely overlaps the portion of the silicon carbide substrate, the gate electrode at least partially overlaps the first source region and at least partially overlaps the second source region;
a source electrode that completely overlaps the gate electrode and at least partially overlaps the first source region and at least partially overlaps the second source region.

11. The device of claim 10, further comprising an insulated-gate region extending over the first body region, the second body region, the first source region, and the second body region, the insulated gate-region including a gate region of a conductive material and an oxide layer covering the gate region.

12. The device of claim 11, wherein the gate region includes:
a first end that terminates on the first source region;
a second end that terminates on the second source region.

13. The device of claim 10, wherein:
the first dimension is between 150 nanometers (nm) and 1000 nanometers (nm); and
the second dimension is between 100 nanometers (nm) and 900 nanometers (nm).

14. The device of claim 13, wherein:
the first dimension is equal to 500 nanometers (nm); and
the second dimension is equal to 350 nanometers (nm).

15. A device, comprising:
a substrate of a first conductivity type;
a first body region having a second conductivity type different from the first conductivity type, the first body region is within the substrate;
a second body region having the second conductivity type, the second body region is within the substrate and spaced apart from the first body region;
a first source region having the first conductivity type, the first source region is within the first body region;
a second source region having the first conductivity type, the second source region is within the second body region;
a first channel region is within the first body region and is between the first source region and the substrate, the first channel having a first channel length along a first direction that extends from the first source region to the substrate;
a second channel region is within the second body region and is between the second source region and the substrate, the second channel region having a second channel length along the first direction that extends from the second source region to the substrate, and the second channel length is greater than the first channel length.

16. The device of claim 15, further comprising an insulated-gate region over the first channel region and the second channel region, the insulated-gate region including a gate region of a conductive material and an oxide layer over the gate region, and the gate region extends over the first channel region and the second channel region.

17. The device of claim 16, wherein the substrate has a surface and the insulated-gate region is on the surface of the substrate, and the first direction is parallel to the surface of the substrate.

18. The device of claim 16, further comprising a gate electrode completely overlaps the insulated-gate region.

19. The device of claim 15, wherein:
the substrate has a first conductivity level of the first conductivity type;
the first source region has a second conductivity level of the first conductivity type greater than the first conductivity level; and
the second source region has a third conductivity level of the first conductivity type greater than the first conductivity level.

20. The device of claim 19, wherein the second conductivity level is the same as the third conductivity level.
